(19) United States
(12) Patent Application Publication
(10) Pub. No.: US 2026/0031773 A1
(43) Pub. Date: Jan. 29, 2026

(54) RADIO-FREQUENCY AMPLIFIER ACCOMMODATING HIGH OUTPUT VOLTAGE SWING

(71) Applicant: Realtek Semiconductor Corp., Hsinchu (TW)

(72) Inventors: Melin Ngwar, Santa Clara, CA (US); Ting-Hsu Chien, Fremont, CA (US); Chia-Liang (Leon) Lin, Fremont, CA (US)

(21) Appl. No.: 18/780,577

(22) Filed: Jul. 23, 2024

(51) Int. Cl. H03F 3/193; H03F 1/30; H03F 3/45

(52) U.S. Cl. CPC H03F 3/193; H03F 1/301; H03F 3/45179; H03F 2200/451

(57) ABSTRACT

An RFA (radio frequency amplifier) includes an NCSA (N-type common-source amplifier) established upon a first source node and configured to receive a first signal and output a first internal current; a first NCGA (N-type common-gate amplifier) configured to receive the first internal current and output a second internal current; a second NCGA configured to receive the second internal current and output a first output current; a PCSA (P-type common-source amplifier) established upon a second source node and configured to receive a second signal and output a third internal current; a first PCGA (P-type common-gate amplifier) configured to receive the third internal current and output a fourth internal current; a second PCGA configured to receive the fourth internal current and output a second output current; and a load network comprising a parallel connection of a primary inductor and a tuning capacitor configured to establish an output signal.

### BACKGROUND OF THE INVENTION

### Field of the Invention

The present invention generally relates to RF (radio frequency) amplifiers and more particularly to RF amplifiers that accommodate high output voltage swing.

### Description of Related Art

Persons of ordinary skill in the art understand terms and basic concepts related to microelectronics that are used in this disclosure, such as “voltage,” “current,” “signal,” “differential signal,” “capacitor,” “inductor,” “resistor,” “transistor,” “MOST (metal-oxide semiconductor field-effect transistor),” “PMOST (p-channel metal-oxide semiconductor field-effect transistor),” “NMOST (n-channel metal-oxide semiconductor field-effect transistor),” “frequency,” “AC (alternating current),” “DC (direct current),” “bias,” “source,” “gate,” “drain,” “(circuit) node,” “ground node,” “power supply node,” “cascode,” “amplifier,” “common-source,” “common-gate,” “transconductance,” “voltage gain,” and “impedance.” Terms and basic concepts like these in the context of the present disclosure are apparent to those of ordinary skill in the art and thus will not be explained in detail here. Those of ordinary skill in the art can read schematics, identify symbols and inter-connections of circuit elements such as inductor, capacitor, resistor, NMOST, and PMOST, and can also identify “source,” “gate,” and “drain” terminals of MOST (either NMOST or PMOST) without the need of detailed descriptions.

A MOST (metal-oxide semiconductor field-effect transistor) is an active device comprising terminals of source, gate, and drain, and can be used to embody an amplifier. A MOST can be either a NMOST (n-channel metal-oxide semiconductor field-effect transistor) or a PMOST transistor (p-channel metal-oxide semiconductor field-effect transistor). A MOST has a threshold voltage. The MOST is in the “saturation region” and can function effectively as an amplifier by converting an input (gate-to-source) voltage into an output (drain) current when the gate-to-source voltage is larger than the threshold voltage but a gate-to-drain voltage is smaller than the threshold voltage. The MOST is in the “triode region” and can function effectively as a switch when the gate-to-source voltage and the gate-to-drain voltage are both larger than the threshold voltage. The effectiveness of a MOST in performing the input (gate-to-source) voltage to output (drain) current conversion also depends on its width-to-length ratio, wherein a higher width-to-length ratio makes the MOST more effective in performing the conversion.

When the gate and the drain of a MOST are tied together, the MOST is said to be configured in a “diode-connect” topology. In this case, the MOST will be in the “saturation region” when the gate-to-source voltage is larger than the threshold voltage, or otherwise turned off, and will never be in the “triode region.”

A MOST can be configured as a common-source amplifier that converts an input voltage received from its gate into an output current delivered via its drain, while its source is usually connected to a sufficiently low-impedance node so that a voltage at its source can remain approximately fixed regardless of a dynamic nature of the input voltage. An incremental change of the input voltage will result in an incremental change of the output current, and a ratio between the latter and the former is known as the “transconductance,” which quantifies how effective the common-source amplifier performs the input (gate) voltage to the output (drain) current conversion. The linearity of a common-source amplifier is gauged by how well the transconductance can maintain substantially the same when a swing of the input voltage increases. To have good linearity, the MOST must remain in the “saturation region” for as large a swing of the input voltage as possible. The transconductance, or effectiveness of input (gate) voltage to output (drain) current conversion, will be reduced in the presence of “source degeneration,” wherein the impedance at the source is not sufficiently low. In many cases, source degeneration adversely hinders the gain and is highly undesirable.

A MOST can also be configured as a common-gate amplifier that receives an input current from its source and delivers an output current via its drain, while its gate is usually connected to a sufficiently low-impedance node so that a voltage at its gate can remain approximately fixed regardless of a dynamic nature of the input current. A common-gate amplifier can effectively relay the input (source) current into the output (drain) current, such that an incremental change of the input (source) current can lead to a substantially equal incremental change of the output (drain) current. When a load is connected to the drain of the MOST and a drain impedance (i.e., impedance at the drain of the MOST) is larger than a source impedance (i.e., impedance at the source of the MOST), a voltage amplification from the source to the drain can be achieved since the output (drain) current is substantially equal to the input (source) current but the drain impedance is greater than the source impedance. In case of a larger gate impedance (i.e., impedance at the gate of the MOST), the function of current relay remains substantially as effective, but the source impedance will be larger and the voltage amplification from the source to the drain will be smaller.

A second MOST can be stacked onto a first MOST of the same type in a “cascode” topology, wherein the first MOST is configured as a common-source amplifier, and the second MOST is configured as a common-gate amplifier that is stacked upon the first MOST and shares the same current path such that an output (drain) current of the first MOST becomes an input (source) current of the second MOST and is then relayed into an output (drain) current of the second MOST. A benefit of the cascode topology is to provide a good reverse isolation, such that a change in a loading condition seen at the drain of the second MOST has little effect on the first MOST.

A signal is either a voltage or current of a variable level that carries certain information and can vary with time. The level of the signal at a moment represents the state of the signal at that moment. A signal is a “voltage signal” (“current signal”) if it is a voltage (current). In this present disclosure, since “voltage signals” appear more often than “current signals,” for brevity a “signal” refers to a “voltage signal” unless it is otherwise specified as a “current signal.”

Throughout this disclosure, “DC” stands for direct current, and “AC” stands for alternating current. A DC node is a node of a substantially fixed electric potential. In particular, “V_{DD}” denotes a first DC node referred to as a power supply node, and “V_{SS}” denotes a second DC node referred to as a ground node. A bias node is a DC node configured to establish a DC voltage level of a gate of a MOST.

Throughout this disclosure, a differential signaling scheme is widely used, wherein a voltage (current) signal comprises a first voltage (current) and a second voltage (current) denoted with suffixes “+” and “−,” respectively, attached in subscript, and the first voltage (current) and the second voltage (current) have substantially the same DC component but opposite AC component. For instance, a voltage signal V_{X} in a differential signaling embodiment comprises two voltages V_{X+} and V_{X-}, wherein V_{X+} and V_{X-} have substantially the same DC component but opposite AC components. When using the differential signaling scheme, two identical circuits are often used in parallel to process or handle the first voltage and the second voltage, respectively, of the signal. Likewise, in a differential (signaling) embodiment, a circuit also comprises two nodes denoted with suffixes “+” and “−,” respectively, attached in subscript.

A schematic diagram of a RF (radio frequency) amplifier 100 is shown in FIG. 1. Here. A differential embodiment is used, wherein an input signal V_{I} comprises two voltages V_{I+} and V_{I-}, and an output signal V_{O} comprises two voltages V_{O+} and V_{O-}. The RF amplifier 100 comprises: a common-source amplifier 110 comprising two NMOST 111 and 112 configured to receive the two voltages V_{I+} and V_{I-} and output two currents I_{D+} and I_{D-}, respectively; a common-gate amplifier 120 comprising two NMOST 121 and 122 configured to receive the two currents I_{D+} and I_{D-} and establish the two voltages V_{O+} and V_{O-}, respectively, across a primary inductor 131P of a balun transformer 131, wherein a secondary inductor 131S of the balun transformer 131 connects to a load 140 to establish a load voltage V_{load}. NMOST 111 and 112 share a common-source node 101 that connects to a ground node “V_{SS}” through a physical connection path that can be modeled as a first parasitic inductor 119. Here, “parasitic inductor” means “unintended inductor that is most likely detrimental but inevitable in an actual implementation.” NMOST 121 and 122 share a common-gate node 102 of a gate bias voltage “V_{GB}.” A center tap of the primary inductor 131P connects to a power supply node “V_{DD}” through a physical connection path that can be modeled as a second parasitic inductor 139. The RF amplifier 100 further comprises a capacitor 132 connected in parallel with the primary inductor 131P to form a resonant network to establish a high impedance at a radio frequency of interest to boost a swing of the output signal V_{O}. The RF amplifier 100 is well known in the prior art and thus not further explained.

In an application of interest wherein the RF amplifier 100 is fabricated on a silicon substrate using a CMOS (complementary metal-oxide semiconductor) process and packaged as an integrated circuit chip that is mounted on a printed circuit board that provides power supply and ground, the first parasitic inductor 119 and the second parasitic inductor 139 may have considerable inductance values that can adversely impact the performance of the RF amplifier 100. Besides, to effectively embody amplification function, it is favorable to let NMOST 111, 112, 121, and 122 have short lengths and thus high width-to-length ratios. However, shorter length MOS transistors are less capable of handling voltage stress and therefore less suitable for applications that demand large output voltage swing. In particular, the output voltage swing can be particularly large in an application scenario where a loading condition of the load 140 causes the common-gate amplifier 120 to see a large impedance at its output.

What is desired is an amplifier that can effectively mitigate parasitic inductance and also can use short length MOST but still can handle large output voltage swing.

### BRIEF SUMMARY OF THIS INVENTION

An objective of the present disclosure is to have an RF (radio frequency) amplifier that uses short length MOST to achieve effective amplification yet can still handle large output voltage swing.

Another objective of the present disclosure is to have an RF (radio frequency) amplifier that can mitigate parasitic inductance.

In an embodiment, an RFA (radio frequency amplifier) comprises: a NCSA (N-type common-source amplifier) established upon a first source node and configured to receive a first signal and output a first internal current; a first NCGA (N-type common-gate amplifier) configured to receive the first internal current and output a second internal current; a second NCGA configured to receive the second internal current and output a first output current; a PCSA (P-type common-source amplifier) established upon a second source node and configured to receive a second signal and output a third internal current; a first PCGA (P-type common-gate amplifier) configured to receive the third internal current and output a fourth internal current; a second PCGA configured to receive the fourth internal current and output a second output current; and a load network comprising a parallel connection of a primary inductor and a tuning capacitor configured to establish an output signal in accordance with a sum of the first output current and the second output current, wherein: the first signal and the second signal are AC (alternating current) coupled from a common RF (radio frequency) signal; the first source node and the second source node are DC (direct current) coupled to a ground node and a power supply node, respectively, through respective electrical conduction paths, but AC coupled to one another via a source coupling capacitor of a low impedance at a frequency of the first signal; the gates of the first NCGA and the first PCGA are tied to a first gate bias voltage and a second gate bias voltage, respectively; and the gates of the second NCGA and the second PCGA are AC coupled to the first gate bias voltage and the second gate bias voltage through a first gate coupling capacitor and a second gate coupling capacitor, respectively.

### BRIEF DESCRIPTION OF THE DRAWINGS

FIG. 1 shows a schematic diagram of a prior art RF (radio frequency) amplifier.

FIG. 2 shows a schematic diagram of an RF amplifier in accordance with an embodiment of the present disclosure.

FIG. 3 shows a schematic diagram of a trifilar transformer that can be used to establish input signals of the RF amplifier of FIG. 2.

FIG. 4 shows a biasing network that can be used to generate bias voltages for the RF amplifier of FIG. 2.

### DETAILED DESCRIPTION OF THIS INVENTION

The present invention relates to RF amplifiers. While the specification describes several example embodiments of the invention considered favorable modes of practicing the invention, it should be understood that the invention can be implemented in many ways and is not limited to the particular examples described below or to the particular manner in which any features of such examples are implemented. In other instances, well-known details are not shown or described to avoid obscuring aspects of the invention.

In this present disclosure, a CSA (common-source amplifier) is called a NCSA (N-type common-source amplifier) if it is embodied by a NMOST; a CSA called a PCSA (P-type common-source amplifier) if it is embodied by a PMOST; a CGA (common-gate amplifier) is called a NCGA (N-type common-gate amplifier) if it is embodied by a NMOST; a CGA called a PCGA (P-type common-gate amplifier) if it is embodied by a PMOST.

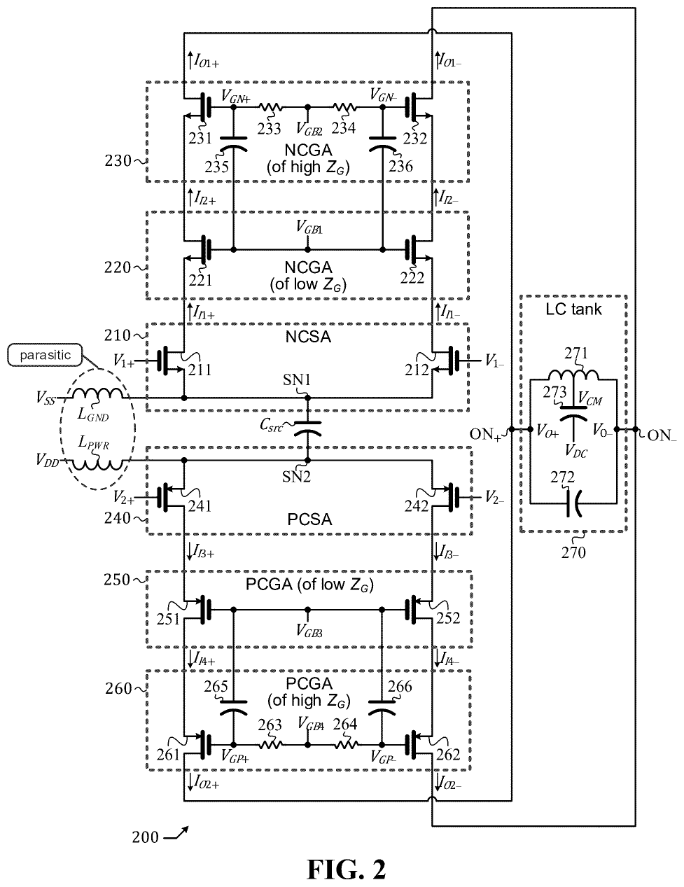

A schematic diagram of an RFA (radio frequency amplifier) 200 in accordance with a differential-signal embodiment of the present disclosure is depicted in FIG. 2. The RFA 200 comprises: a NCSA (N-type common-source amplifier) 210 configured to receive a first signal V₁ (comprising two voltages V₁₊ and V₁₋) and output a first internal current signal I_{I1} (comprising two currents I_{I1+} and I_{I1-}); a first NCGA (N-type common-gate amplifier) 220 configured to receive the first internal current signal I_{I1} and output a second internal current signal I_{I2} (comprising two currents I_{I2+} and I_{I2-}); a second NCGA 230 configured to receive the second internal current signal I_{I2} and output a first output current signal I_{O1} (comprising two currents I_{O1+} and I_{O1-}) to an output node ON (comprising two nodes ON₊ and ON₋ in the differential embodiment); a PCSA (P-type common-source amplifier) 240 configured to receive a second signal V₂ (comprising two voltages V₂₊ and V₂₋) and output a third internal current signal I_{I3} (comprising two currents I₃₊ and I_{I3-}); a first PCGA (P-type common-gate amplifier) 250 configured to receive the third internal current signal I_{I3} and output a fourth internal current signal I_{I4} (comprising two currents I_{I4+} and I_{I4-}); a second PCGA 260 configured to receive the fourth internal current signal I_{I4} and output a second output current signal I_{O2} (comprising two currents I_{O2+} and I_{O2-}) to the output node ON; and a LC tank 270 connected to the output node (ON₊ and ON₋) and comprising a parallel connection of a tuning capacitor 272 and a primary inductor 271 with a center tap connected to a DC (direct current) node V_{DC} via a common-mode capacitor 273.

NCSA 210 is established upon a first source node SN1 and comprises NMOST 211 and NMOST 212 configured to receive V₁₊ and V₁₋ and output I_{I1+} and I_{I1-}, respectively. The first source node SN1 is DC coupled to a ground node “V_{SS}” via an electrical conduction path that can be modeled as a first parasitic inductor L_{GND}. PCSA 240 is established upon a second source node SN2 and comprises PMOST 241 and PMOST 242 configured to receive V₂₊ and V₂₋ and output I_{I3+} and I_{I3-}, respectively. The second source node SN2 is DC coupled to a power supply node “V_{DD}” via an electrical conduction path that can be modeled as a second parasitic inductor L_{PWR}. The RFA 200 further comprises a source coupling capacitor C_{src} configured to provide a strong AC (alternating current) coupling between the first source node SN1 and the second source node SN2, wherein the capacitance of the source coupling capacitor C_{src} is sufficiently large such that the source capacitor C_{src} has substantially smaller impedance than at least one of the first parasitic inductor L_{GND} and the second parasitic inductor L_{PWR}.

NCGA 220 comprises NMOST 221 and NMOST 222 configured to receive I_{I1+} and I_{I1-} and output I_{I2+} and I_{I2-}, respectively. The gates of NMOST 221 and NMOST 222 connect to a first gate bias node of voltage V_{GB1} and of low impedance (low “Z_{G}”) that is substantially lower than the impedance that I_{I1+} and I_{I1-} see when looking into NCGA 220. NCGA 230 comprises NMOST 231 and NMOST 232 configured to receive I_{I2+} and I_{I2-} and output I_{O1+} and I_{O1-}, respectively. The gates of NMOST 231 and NMOST 232 are DC (direct current) coupled to a second gate bias node of voltage V_{GB2} via a first pair of gate coupling resistors 233 and 234, and AC coupled to the first gate bias node of V_{GB1} via a first pair of gate coupling capacitors 235 and 236, respectively. At the frequency of the first signal V₁₊ and V₁₋, the impedance of the first pair of gate coupling capacitors 235 and 236 is lower than the impedance of the first pair of gate coupling resistors 233 and 234 but higher than the impedance at the first gate bias node of V_{GB1}. That's why NCGA 220 is said to be of a low gate impedance (Z_{G}), while the NCGA 230 is said to be of a high gate impedance (Z_{G}).

PCGA 250 comprises PMOST 251 and 252 configured to receive I_{I3+} and I_{I3-} and output I_{I4+} and I_{I4-}, respectively. The gates of PMOST 251 and PMOST 252 connect to a third gate bias node of voltage V_{GB3} of low impedance (low “Z_{G}”) that is substantially lower than the impedance that I_{I3+} and I_{I3-} see when looking into the first PCGA 250. PCGA 260 comprises PMOST 261 and PMOST 262 configured to receive I_{I4+} and I_{I4-} and output I_{O2+} and I_{O2-}, respectively. The gates of PMOST 261 and PMOST 262 are DC (direct current) coupled to a fourth gate bias node of voltage V_{GB4} via a second pair of gate coupling resistors 263 and 264, and AC coupled to the third gate bias node of V_{GB3} via a second pair of gate coupling capacitors 265 and 266, respectively. At the frequency of the second signal V₂₊ and V₂₋, the impedance of the second pair of gate coupling capacitors 265 and 266 is lower than the impedance of the second pair of gate coupling resistors 263 and 264 but higher than the impedance at the third gate bias node of V_{GB3}. That's why PCGA 250 is said to be of a low gate impedance (Z_{G}), while PCGA 260 is said to be of a high gate impedance (Z_{G}).

The first signal V₁ (comprising V₁₊, V₁₋) and the second signal V₂ (comprising V₂₊, V₂₋) are RF signals that are of the same frequency and similar AC swings but different DC levels. Mathematically, in an embodiment, V₁₊, V₁₋, V₂₊, and V₂₋ can be modeled by the following equations:

$${V}_{1 +} = {V}_{BN} + {A}_{N} ( t ) sin ( ω t + {φ}_{N} ( t ) ) \qquad ( 1 )$$

$${V}_{1 -} = {V}_{BN} - {A}_{N} ( t ) sin ( ω t + {φ}_{N} ( t ) ) \qquad ( 2 )$$

$${V}_{2 +} = {V}_{BP} + {A}_{P} ( t ) sin ( ω t + {φ}_{P} ( t ) ) \qquad ( 3 )$$

$${V}_{2 -} = {V}_{BP} - {A}_{P} ( t ) sin ( ω t + {φ}_{P} ( t ) ) \qquad ( 4 )$$

Here, t denotes a time variable; ω denotes an angular frequency of an input signal; V_{BN} denotes a first DC (direct current) bias level of V₁₊ and V₁₋; V_{BP} denotes a second DC bias level of V₂₊ and V₂₋; A_{N}(t) and φ_{N}(t) denote time-varying amplitude and phase, respectively, of the first signal V₁; and A_{P}(t) and φ_{P}(t) denote time-varying amplitude and phase, respectively, of the second signal V₂. V_{BN} determines a DC level and correspondingly a biasing condition of NMOST 211 and 212, while V_{BP} determines a DC level and correspondingly a biasing condition of PMOST 241 and 242. In a preferred yet nonbinding embodiment, A_{N}(t) is the same as A_{P}(t), while φ_{N}(t) is the same as φ_{P}(t).

The first signal V₁ (comprise V₁₊ and V₁₋) and the second signal V₂ (comprising V₂₊, and V₂₋) are originated from a common RF signal V_{I} (comprising two voltages V_{I+} and V_{I-} in a differential embodiment), wherein V₁ and V₂ are both AC coupled to V_{I} but DC (direct current) coupled into the first DC bias level V_{BN} and the second DC bias level V_{BP}, respectively.

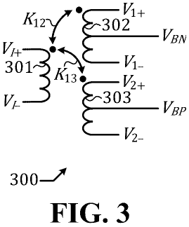

As depicted in FIG. 3, in an embodiment, V₁₊, V₁₋, V₂₊, and V₂₋ are AC coupled from V_{I+} and V_{I-} using a trifilar transformer 300 comprising: a first inductor 301 configured to receive V_{I+} and V_{I-}; a second inductor 302 configured to couple V_{I+} and V_{I-} into V₁₊ and V₁₋ via a first magnetic coupling K₁₂ with the first inductor 301; and a third inductor 303 configured to couple V_{I+} and V_{I-} into V₂₊ and V₂₋ via a second magnetic coupling K₁₃ with the first inductor 301. The center taps of the second inductor 302 and the third inductor 303 connect to DC voltages of V_{BN} and V_{BP}, respectively.

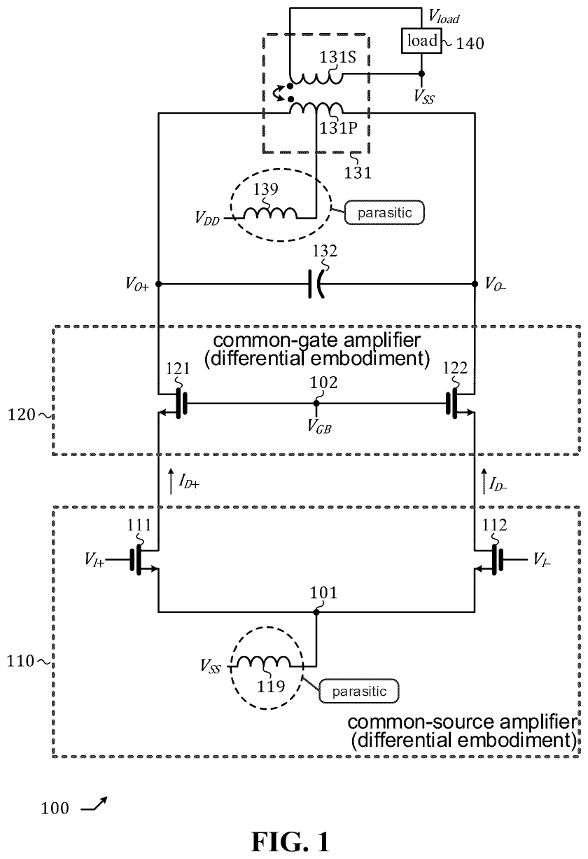

The LC tank 271 is configured to provide a high impedance due to forming a resonant network between the primary inductor 271, the tuning capacitor 272, and a parasitic capacitance at the output node (comprising ON₊ and ON₋ in the differential embodiment). Currents I_{O1+} and I_{O2+} are summed at ON₊, while currents I_{O1-} and I_{O2-} are summed at ON₋. When the LC tank 271 have a high impedance, the output signal V_{O} (comprising V_{O+} and V_{O-} in the differential embodiment) can have a large swing. In a further embodiment not shown in the figure, RFA 200 further includes a secondary inductor terminated with a load and configured to have a strong magnetic coupling with the primary inductor 271 to couple V_{O+} and V_{O-} to a load voltage at the load. In this case, the secondary inductor and the primary inductor 271 form a balun transformer, just like the balun transformer 131 of FIG. 1. A loading condition of the load may cause V_{O+} and V_{O-} to have a large voltage swing. However, thanks to the higher gate impedance of NCGA 230 and PCGA 260, an otherwise serious voltage stress issue can be mitigated.

Both NCSA 210 and PCSA 240 are common-source amplifiers known in the prior art and therefore are not further explained in detail. Like the prior art, the parasitic inductors L_{GND} and L_{PWR} could result in source degeneration that adversely affect the performance of NCSA 210 and PCSA 240. Unlike the prior art, however, thanks to using the source coupling capacitor C_{src}, the first source node SN1 and the second source SN2 are effectively short-circuited, causing L_{GND} and L_{PWR} to be rendered irrelevant and seemingly non-existing, provided an impedance of the source coupling capacitor C_{src} is substantially smaller than the impedance of L_{GND} and L_{PWR}. This way, NCSA 210 and PCSA 240 can effectively mitigate an undesired source degeneration due to parasitic inductance that often plagues prior art common-source amplifiers. In reality, L_{GND} is usually smaller than L_{PWR} in inductance. In a case where L_{GND} is sufficiently small and won't cause appreciable source degeneration to NCSA 210 even in the absence of the source coupling capacitor C_{src}, the impedance of the source coupling capacitor C_{src} only needs to be substantially smaller than the impedance of L_{PWR} to mitigate the source degeneration effect of L_{PWR}.

NCGA 220 and PCGA 250 are similar to conventional common-gate amplifiers well known in the prior art and therefore not further explained in detail. NCGA 230 and PCGA 260, however, differ from conventional common-gate amplifiers in that their gate impedance is not very low. Conventional common-gate amplifiers have a low gate impedance so that an input impedance can be low and consequently a voltage gain can be high. Due to having a higher gate impedance (compared to a conventional common-gate amplifier), NCGA 230 and PCGA 260 have a higher input impedance (as seen by I₂₊, I₂₋, I₄₊, and I₄₋,) and thus will have a lower voltage gain. However, the higher input impedance of NCGA 230 and PCGA 260 causes NCGA 220 and PCGA 250 to see a higher load impedance and thus higher voltage gain. Consequently, the cascaded voltage gain of NCGA 220 (PCGA 250) and NCGA 230 (PCGA 260) can be approximately the same as that in the case where NCGA 230 (PCGA 260) has a lower gate impedance. This result makes sense, as both NCGA 220 (PCGA 250) and NCGA 230 (PCGA 260) are current mode circuits that simply relay their respective input currents into their respective output circuits, and therefore I_{O1+} (I_{O2+}) and I_{O1-} (I_{O2-}) must be approximately equal to I₁₊ (I₃₊) and I₁₋ (I₃₋) regardless of the gate impedance of NCGA 230 (PCGA 260). Therefore, the voltage amplification function can be preserved, despite the fact that NCGA 230 (PCGA 260) has a higher gate impedance and therefore higher input impedance. Purposedly devising NCGA 230 (PCGA 260) to have a higher gate impedance, however, allows gate voltages V_{GN+} (V_{GP+}) and V_{GN-} (V_{GP-}) of NMOST 231 (PMOST 261) and NMOST 232 (PMOST 262) to somewhat bounce together with output voltages V_{O+} and V_{O-} due to a parasitic gate-to-drain capacitance of NMOST 231 (PMOST 261) and NMOST 232 (PMOST 262). This way, in the presence of a large voltage swing of V_{O+} and V_{O-}, the gate-to-drain voltage of NMOST 231 (PMOST 261) and NMOST 232 (PMOST 262) can be lower, compared to the case where the gate impedance of NMOST 231 (PMOST 261) and NMOST 232 (PMOST 262) is lower and consequently the gate voltages V_{GN+} (V_{GP+}) and V_{GN-} (V_{GP-}) are more stationary. In a nutshell, voltage stress can be relieved without sacrificing an overall voltage gain, despite having a higher gate impedance in NCGA 230 and PCGA 260.

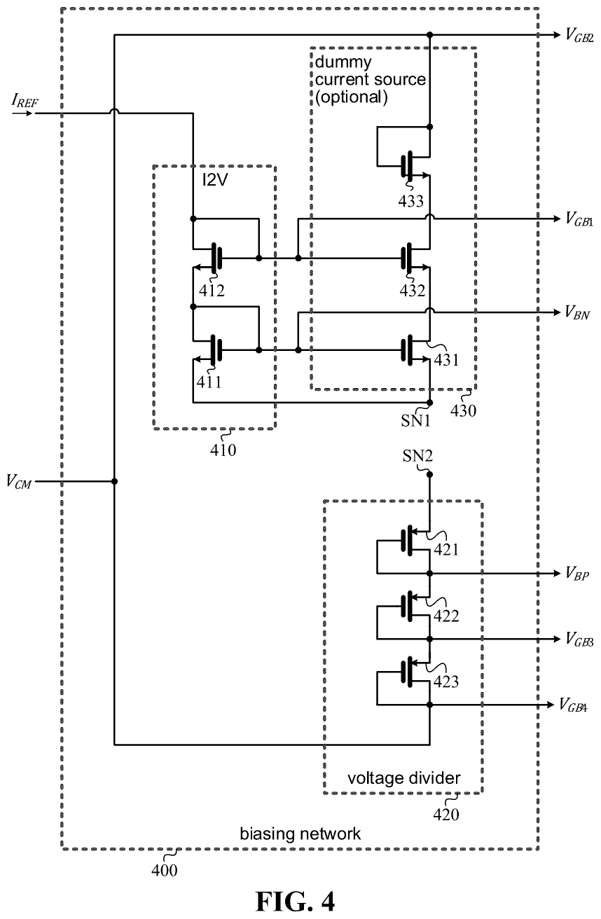

RFA 200 along with trifilar transformer 300 need six DC biasing voltages: V_{BN} (for biasing NCSA 210 through trifilar 300), V_{GB1} (for biasing NCGA 220), V_{GB2} (for biasing NCGA 230), V_{BP} (for biasing PCSA 240 through trifilar 300), V_{GB3} (for biasing PCGA 250), and V_{GB4} (for biasing PCGA 260). The DC voltage level of the output signal V_{O} (comprising V_{O+} and V_{O-}) is equal to the DC voltage level of a common-mode voltage V_{CM} at the common-mode capacitor 273 (connected to the center tap of the primary inductor 271) and is determined by a biasing condition of RFA 200. In an embodiment, the six DC biasing voltages are controlled by a biasing network in accordance with a reference current I_{REF} and V_{CM}, wherein I_{REF} controls V_{BN} and V_{G1}, while V_{CM} controls V_{BP}, V_{G2}, V_{G3}, and V_{G4}. Since V_{CM} is determined by the biasing condition of RFA 200, but the biasing condition of RFA 200 is also controlled by V_{CM}, a feedback control loop is formed. In particular, the feedback control loop must have a negative feedback nature such that a rise (fall) of V_{CM} will lead to a rise (fall) of V_{BP}, V_{G2}, V_{G3}, and V_{G4} to lower (raise) V_{CM} and thus amend the rise (fall) of V_{CM}; this way, V_{CM} can settle into a stable point. As shown in FIG. 4, an exemplary embodiment of a biasing network 400 comprises: a current-to-voltage converter (I2V) 410 configured to receive the reference current I_{REF} and output V_{BN} and V_{GB1}, and V_{GB2} (which is directly tied to V_{CM}) to control NCSA 210, NCGA 220, and NCGA 230, respectively; and a voltage divider 420 configured to receive V_{CM} and output V_{BP}, V_{GB3}, and V_{GB4} (which is directly tied to V_{CM}) to control PCSA 240, PCGA 250, and PCGA 260, respectively. I2V 410 comprises NMOST 411 and NMOST 412, both configured in a “diode-connect” topology. V_{BN} and V_{GB1} are determined such that NMOST 411 and MOST 412, respectively, can provide a drain current that is equal to I_{REF}; this can be well understood by those of ordinary skill in the art and thus not further explained. Using V_{BN} and V_{GB1} to control NCSA 210 and NCGA 220, respectively, can ensure that the DC current of I₂₊ (I₂₋) and consequently the DC current of I_{O1+} (I_{O1-}) can be well controlled and approximately equal to I_{REF} times a scaling factor determined by the width-to-length ratios of NMOST 411 and NMOST 211 (NMOST 212); this can also be well understood by those of ordinary skill in the art and thus not further explained. V_{GB2} and V_{GB4} are directly tied to V_{CM}, therefore, NMOST 231, NMOST 232, PMOST 261, and PMOST 262 will not enter the “triode region” in a static condition. The voltage divider 420 comprises PMOST 421, PMOST 422, and PMOST 423, all configured in a diode-connect topology to determine V_{BP} and V_{GB3}. When the DC level of V_{CM} rises (falls), V_{BP}, V_{GB3}, and V_{CB4} all rise (fall), causing PMOSTs 241, 242, 251, and 252 to have smaller gate-to-source voltages and thus lower DC currents; consequently, the DC currents of I_{O2+} and I_{O2-} will fall (rise), and the DC level of V_{CM} will fall (rise). This way, a negative feedback control loop is formed to counter a change of the DC level of V_{CM} and cause it to settle to a level determined by the DC currents of I_{O1+} and I_{O1-} that are controlled by I_{REF}. In summary, the DC currents of NCSA 210, NCGA 220, and NCGA 230, and therefore the DC level of I_{O1+} and I_{O-} are all determined by I_{REF}, and the NMOSTs therein can be surely biased in the saturation region (due to using the I2V 410), while V_{CM}, V_{BP}, V_{GB3}, and V_{CB4} are determined in a closed-loop negative feedback control manner in accordance with the DC level of I_{O1+} and I_{O-}. PMOST 421 (422, 423) of the voltage divider 420 mimics PMOST 241 (251, 261) and PMOST 242 (252, 262) of PCSA 240 (PCGA 250, PCGA 260). This way, all the PMOSTs in RFA 200 can be surely biased in the saturation region due to using the voltage divider 420 that ensures PMOSTs 421, 422, and 423 are all in the saturation region.

In an optional embodiment, the biasing network 400 further includes a dummy current source 430 comprising three NMOSTs 431, 432, and 433 configured to mimic NMOST 211 (212), NMOST 221 (222) and NMOST 231 (232), respectively. The dummy current source 430 is not absolutely needed, as far as the functionality of the biasing network 400 is concerned, but it helps to make the overall circuit of RFA 200 and the biasing network 400 more balanced, as the dummy current source 430 can balance the voltage divider 420, so that a current flowing from the second source node SN2 to V_{CM} through the voltage divider 420 can be offset by a current flowing from V_{CM} to the first source node SN1 via the dummy current source 430.

The function of I2V is to generate V_{BN} and V_{GB1} such that the DC levels of I_{O1+} and I_{O1-} can be approximately equal to I_{REF} times a well-controlled factor pertaining to width-to-length ratios of related NMOSTs. The function of the voltage divider 420 is to generate V_{BP} and V_{GB3} in a way that an incremental change of V_{CM} leads to an incremental change of V_{BP} and V_{GB3} in the same direction but of lesser amount. The function of the optional dummy current source 430 is to complement the voltage divider 420 and thus form a balanced load to V_{CM}. Note that I2V 410, voltage divider 420, and the optional dummy current source 430 are just exemplary embodiments and it is not necessary to use exactly the same circuits as what are shown in FIG. 4 and one can use alternative embodiments as long as their respective functions are preserved and fulfilled. In an alternative embodiment not shown in the figure, the roles of NMOSTs and PMOSTs are swapped, V_{BN} and V_{BP} are swapped, V_{GB1} and V_{GB3} are swapped, V_{GB2} and V_{GB4} are swapped, and SN1 and SN2 are swapped: the I2V 410 is changed to comprise two PMOSTs (instead of NMOSTs 411 and 412) and generate V_{BP} and V_{GB3} (instead of V_{BN} and V_{GB1}) such that the DC levels of I_{O2+} and I_{O2-} (instead of I_{O1+} and I_{O1-}) can be approximately equal to I_{REF} times a well-controlled factor pertaining to width-to-length ratios of related PMOSTs; the voltage divider 420 is changed to comprise three NMOSTs (instead of PMOSTs 421, 422, and 423) and generate V_{BN}, V_{GB1}, and V_{GB2} (instead of V_{BP}, V_{GB3}, and V_{GB4\3}); the optional dummy current source 430 is changed to comprise three PMOSTs (instead of NMOSTs 431, 432, and 433) controlled by V_{BP} and V_{GB3} (instead of V_{BN} and V_{GB1}). This alternative embodiment is based on a general principle that, in any MOST circuits, replacing every NMOST with a PMOST, replacing every PMOST with a NMOST, replacing every power supply node with a ground node, and replacing every ground node with a power supply node will result in an alternative circuit that can have exactly the function as the original circuit, as long as the biasing condition is properly set.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An RFA (radio frequency amplifier) comprising:
a NCSA (N-type common-source amplifier) established upon a first source node and configured to receive a first signal and output a first internal current;
a first NCGA (N-type common-gate amplifier) configured to receive the first internal current and output a second internal current;
a second NCGA configured to receive the second internal current and output a first output current;
a PCSA (P-type common-source amplifier) established upon a second source node and configured to receive a second signal and output a third internal current;
a first PCGA (P-type common-gate amplifier) configured to receive the third internal current and output a fourth internal current;
a second PCGA configured to receive the fourth internal current and output a second output current; and
a load network comprising a parallel connection of a primary inductor and a tuning capacitor configured to establish an output signal in accordance with a sum of the first output current and the second output current, wherein: the first signal and the second signal are AC (alternating current) coupled from a common RF (radio frequency) signal; the first source node and the second source node are DC (direct current) coupled to a ground node and a power supply node, respectively, through respective electrical conduction paths, but AC coupled to one another via a source coupling capacitor of a low impedance at a frequency of the first signal; the gates of the first NCGA and the first PCGA are tied to a first gate bias voltage and a second gate bias voltage, respectively; and the gates of the second NCGA and the second PCGA are AC coupled to the first gate bias voltage and the second gate bias voltage through a first gate coupling capacitor and a second gate coupling capacitor, respectively.

2. The RFA of claim 1, wherein the first signal and the second signal are DC coupled into a first DC bias voltage and a second DC bias voltage, respectively.

3. The RFA of claim 2, wherein the first signal and the second signal are generated from the common RF signal using a trifilar transformer comprising a first inductor configured to receive the common RF signal; a second inductor configured to have a strong magnetic coupling with the first inductor to couple the common RF signal into the first signal, a center tap of the second inductor being tied to the first DC bias voltage; and a third inductor configured to have a strong magnetic coupling with the first inductor to couple the common RF signal into the second signal, a center tap of the third inductor being tied to the second DC bias voltage.

4. The RFA of claim 2, wherein the gates of the second NCGA and the second PCGA are DC coupled to a third gate bias voltage and a fourth gate bias voltage through a first gate coupling resistor and a second gate coupling resistor, respectively.

5. The RFA of claim 4, further comprising a biasing network configured to receive a reference current and a common-mode voltage at a center tap of the primary inductor and output the first DC bias voltage, the second DC bias voltage, the first gate bias voltage, the second gate bias voltage, the third gate bias voltage, and the fourth gate bias voltage.

6. The RFA of claim 5, wherein the first DC bias voltage and the first gate bias voltage are determined by the reference current in accordance with a current-to-voltage conversion.

7. The RFA of claim 6, wherein the first DC bias voltage, the second gate bias voltage, the third gate bias voltage, and the fourth gate bias voltage are determined by the common-mode voltage in a negative feedback control manner.

8. The RFA of claim 7, wherein the third gate bias voltage and the fourth gate bias voltage are directly tied to the common-mode voltage.

9. The RFA of claim 8, wherein the biasing network comprises: a current-to-voltage converter configured to receive the reference current and output the first DC bias voltage and the first gate bias voltage; and a voltage divider configured to receive the common-mode voltage and output the second DC bias voltage and the second gate bias voltage.

10. The RFA of claim 9, wherein the current-to-voltage converter comprises a stack of two diode-connect NMOSTs (N-channel metal-oxide semiconductor field-effect transistors).

11. The RFA of claim 9, wherein the voltage divider comprises a stack of three diode-connect PMOSTs (P-channel metal-oxide semiconductor field-effect transistors).

12. The RFA of claim 9, wherein the biasing network further comprises a dummy current source configured to balance a load of the voltage divider to the common-mode voltage.
